(19) United States
(12) Patent Application Publication
(10) Pub. No.: US 2025/0176166 A1
(43) Pub. Date: May 29, 2025

(54) SEMICONDUCTOR MEMORY DEVICES

(71) Applicant: Samsung Electronics Co., Ltd., Suwon-si (KR)

(72) Inventors: Hongjun Lee, Suwon-si (KR); Huijung Kim, Suwon-si (KR); Hyunjin Lee, Suwon-si (KR); Heejae Chae, Suwon-si (KR)

(21) Appl. No.: 18/888,261

(22) Filed: Sep. 18, 2024

(30) Foreign Application Priority Data
Nov. 29, 2023 (KR) 10-2023-0170037

(51) Int. Cl. H10B 12/00

(52) U.S. Cl. CPC H10B 12/39; H10B 12/50

(57) ABSTRACT

Provided is a semiconductor memory device including a semiconductor substrate, a plurality of memory active regions each having a long axis and a short axis, and arranged to maintain a first distance between memory active regions along the short axis and maintain a second distance between memory active regions along the long axis, a plurality of logic active regions each including at least a P-channel metal oxide semiconductor transistor and arranged to maintain a third distance therebetween, a first device isolation insulating layer in the first trench with a first portion that corresponds to a region between the memory active regions other along the direction of the long axis including a first nitride insulating layer, and a second device isolation insulating layer in the second trench between the logic active regions and that does not include the first nitride insulating layer, wherein the second distance is substantially the same as the third distance.

### CROSS-REFERENCE TO RELATED APPLICATION

This application is based on and claims priority under 35 U.S.C. § 119 to Korean Patent Application No. 10-2023-0170037, filed on Nov. 29, 2023, in the Korean Intellectual Property Office, the disclosure of which is incorporated by reference herein in its entirety.

### BACKGROUND

The inventive concept relates to a semiconductor memory device, and more particularly, to a semiconductor memory device having a memory cell region and a peripheral region.

In accordance with the rapid development of the electronics industry and user demands, electronic products are becoming increasingly smaller and lighter. Accordingly, high integration may be required for a semiconductor memory device used in the electronic products. A demand for high integration for a semiconductor memory device applies not only to components within a memory cell region of the semiconductor memory device, but also to components within a peripheral region located around the memory cell region. Accordingly, while maintaining reliability of the operation of the semiconductor memory device, there is a demand for miniaturization and higher integration of the semiconductor memory device.

### SUMMARY

The inventive concept provides semiconductor memory devices whose sizes are reduced while maintaining the reliable operation of the semiconductor memory devices.

According to an aspect of the inventive concept, there is provided a semiconductor memory device including a semiconductor substrate including a cell portion in a cell region, a peripheral portion in a peripheral region disposed around the cell region, and a boundary portion in a boundary region between the cell region and the peripheral region, a plurality of memory active regions defined by a first trench in the cell region, each of the memory active regions having a long axis and a short axis, wherein each of the memory active regions is arranged to maintain a first distance between adjacent memory active regions along a direction of the short axis and each of the memory active regions is arranged to maintain a second distance between adjacent memory active regions along a direction of the long axis, and a plurality of logic active regions defined by a second trench in the peripheral region, wherein each of the logic active regions includes at least a P-channel metal oxide semiconductor (PMOS) transistor, and each of the logic active regions is arranged to maintain a third distance between adjacent logic active regions, a first device isolation insulating layer partially formed in the first trench, wherein a first portion of the first device isolation insulating layer that corresponds to a region between the memory active regions that are adjacent to each other along the direction of the long axis comprises a first nitride insulating layer, and a second device isolation insulating layer partially formed in the second trench between the logic active regions and that does not include the first nitride insulating layer, wherein the second distance is substantially the same as the third distance.

According to another aspect of the inventive concept, there is provided a semiconductor memory device including a semiconductor substrate including a cell region, a peripheral region disposed around the cell region, and a boundary region between the cell region and the peripheral region, a plurality of memory active regions defined by a first trench in the cell region, each of the memory active regions having a long axis and a short axis, wherein each of the memory active regions is arranged to maintain a first distance between adjacent memory active regions along a direction of the short axis and each of the memory active regions is arranged to maintain a second distance between adjacent memory active regions along the direction of the long axis, and a plurality of logic active regions defined by a second trench in the peripheral region, wherein each of the logic active regions include at least a PMOS transistor, and each of the logic active regions is arranged to maintain a third distance between adjacent logic active regions, a first device isolation insulating layer partially formed in the first trench, wherein a first portion of the first device isolation insulating layer that corresponds to a region between the memory active regions that are adjacent to each other along the direction of the long axis includes a first nitride insulating layer, and a second device isolation insulating layer partially formed in the second trench, wherein the second device isolation insulating layer includes the first nitride insulating layer, wherein the second distance is substantially the same as the third distance, and a vertical level of an upper end of the first nitride insulating layer of the second device isolation insulating layer is located at half of the depth of the second trench or below.

According to another aspect of the inventive concept, there is provided a semiconductor memory device including a semiconductor substrate including a cell region, a peripheral region disposed around the cell region, and a boundary region between the cell region and the peripheral region, a plurality of memory active regions defined by a first trench in the cell region, each of the memory active regions having a long axis and a short axis, wherein each of the memory active regions is arranged to maintain a first distance between adjacent memory active regions along a direction of the short axis and each of the memory active regions is arranged to maintain a second distance between adjacent memory active regions along a direction of the long axis; and a plurality of logic active regions defined by a second trench in the peripheral region, wherein the plurality of logic active regions include at least a PMOS transistor, and the plurality of logic active regions adjacent to each other are arranged while maintaining a third distance therebetween, a first device isolation insulating layer that is partially formed in the first trench and that includes a first silicon nitride layer formed below an upper end of the first trench, a second device isolation insulating layer that is partially formed in the second trench between logic active regions that are adjacent to each other and that does not include the first silicon nitride layer, and a third device isolation insulating layer that is partially formed in a third trench in the boundary region between an outermost memory active region of the plurality of memory active regions and an innermost logic active region of the plurality of logic active regions, wherein the third device isolation insulating layer is asymmetrically formed in a vertical cross-section between the innermost logic active region and the outermost memory active region, wherein the second distance is substantially the same as the third distance.

### BRIEF DESCRIPTION OF THE DRAWINGS

Embodiments will be more clearly understood from the following detailed description taken in conjunction with the accompanying drawings in which:

FIG. 1 is a block diagram for explaining a semiconductor memory device according to some embodiments;

FIG. 2 is a schematic layout for explaining the main components of a semiconductor memory device according to some embodiments;

FIG. 3 is a cross-sectional view of a semiconductor memory device according to some embodiments;

FIG. 4 is an enlarged cross-sectional view of an ‘A’ part of FIG. 3;

FIG. 5 is a cross-sectional view showing a state of semiconductor device during a method of manufacturing a semiconductor memory device according to some embodiments;

FIG. 6 is a cross-sectional view showing a state of a semiconductor device during a method of manufacturing the semiconductor memory device according to some embodiments.

FIG. 7 is a cross-sectional view showing a state of a semiconductor device during a method of manufacturing the semiconductor memory device according to some embodiments.

FIG. 8 is a cross-sectional view showing a state of a semiconductor device during a method of manufacturing the semiconductor memory device according to some embodiments.

FIG. 9 is a cross-sectional view showing a state of a semiconductor device during a method of manufacturing the semiconductor memory device according to some embodiments.

FIG. 10 is a cross-sectional view showing a state of a semiconductor device during a method of manufacturing the semiconductor memory device according to some embodiments.

FIG. 11 is a cross-sectional view showing a state of a semiconductor device during a method of manufacturing the semiconductor memory device according to some embodiments.

FIG. 12 is a cross-sectional view of a semiconductor memory device according to some embodiments;

FIG. 13 is an enlarged cross-sectional view showing another embodiment corresponding to a ‘B’ part of FIG. 15;

FIG. 14 is a cross-sectional view showing a state of a semiconductor device during a method of manufacturing the semiconductor memory device according to some embodiments;

FIG. 15 is a cross-sectional view showing a state of a semiconductor device during a method of manufacturing the semiconductor memory device according to some embodiments;

FIG. 16 is a cross-sectional view showing a state of a semiconductor device during a method of manufacturing the semiconductor memory device according to some embodiments;

FIG. 17 is a cross-sectional view of a semiconductor memory device according to some embodiments;

FIG. 18 is an enlarged cross-sectional view of a ‘C’ part of FIG. 17;

FIG. 19 is a cross-sectional view showing a state of a semiconductor device during a method of manufacturing a semiconductor memory device according to some embodiments;

FIG. 20 is a cross-sectional view showing a state of a semiconductor device during a method of manufacturing a semiconductor memory device according to some embodiments;

FIG. 21 is a cross-sectional view showing a state of a semiconductor device during a method of manufacturing a semiconductor memory device according to some embodiments;

FIG. 22 is a cross-sectional view showing a state of a semiconductor device during a method of manufacturing a semiconductor memory device according to some embodiments; and

FIG. 23 is a cross-sectional view showing a state of a semiconductor device during a method of manufacturing a semiconductor memory device according to some embodiments.

### DETAILED DESCRIPTION OF THE EMBODIMENTS

Hereinafter, some embodiments will be described in detail with reference to the accompanying drawings. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”. When referring to relationships between at least one plurality of items, it will be understood that unless otherwise specified the relationship between individual items in the plurality may be one-to-one, many-to-one, one-to-many, and/or many-to-many unless otherwise specified or as the context makes clear.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

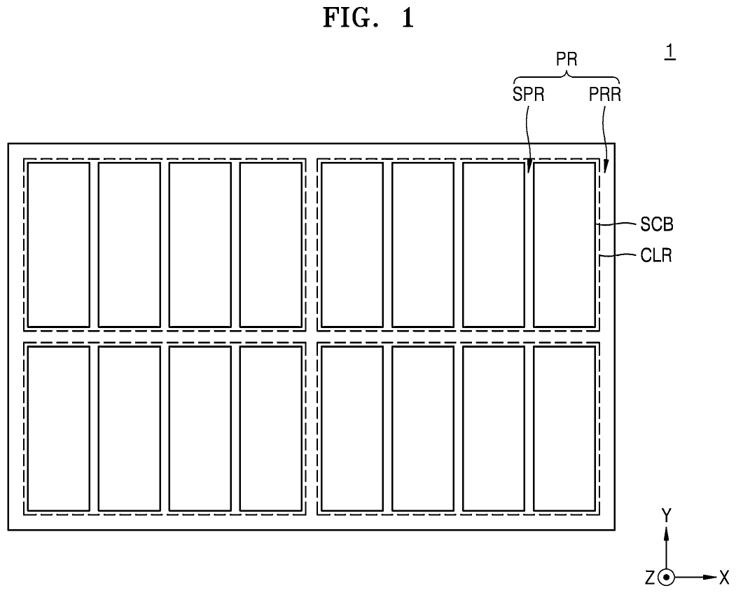

FIG. 1 is a block diagram for explaining a semiconductor memory device 1 according to some embodiments.

Referring to FIG. 1, the semiconductor memory device 1 may include a cell region CLR in which a plurality of semiconductor memory cells is disposed and a main peripheral region PRR surrounding the cell region CLR.

According to some embodiments, the cell region CLR may include a plurality of cell blocks SCBs in which each cell block SCB is separated by a sub-peripheral region SPR. Each of the cell blocks SCB may include a plurality of semiconductor memory cells. As used herein, the cell block SCB refers to a region where the semiconductor memory cells are regularly arranged at predetermined intervals, and the cell block SCB may also be referred to as a sub-cell block.

A plurality of logic cells may be in the main peripheral region PRR and the sub-peripheral region SPR and may input/output (i.e., send/receive) electrical signals to/from the semiconductor memory cells. In some embodiments, the main peripheral region PRR may be referred to as a peripheral circuit region, and the sub-peripheral region SPR may be referred to as a core circuit region. A peripheral region PR may include the main peripheral region PRR and the sub-peripheral region SPR. For example, the peripheral region PR may be a circuit region including the peripheral circuit region and the core circuit region. In some embodiments, at least a portion of the sub-peripheral region SPR may be provided only as a space for separating the cell blocks SCB.

Hereinafter, a region in which the semiconductor memory cells are regularly arranged may be referred to as a “cell region CR” or a “memory cell region CR”, a region in which the logic cells are arranged around the cell region CR may be referred to as the “peripheral region PR”, and a region between the cell region CR and the peripheral region PR may be referred to as a “boundary region BR”.

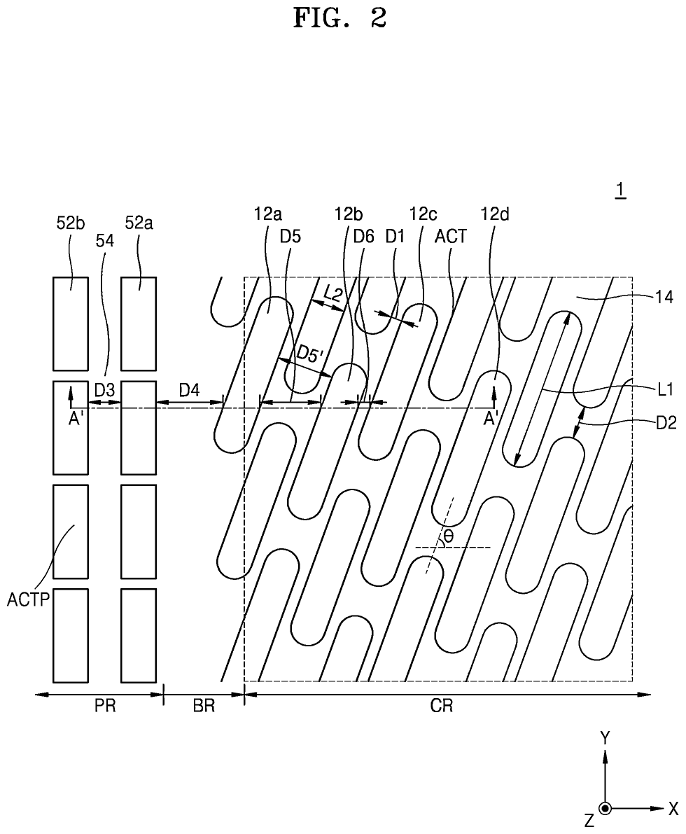

FIG. 2 is a schematic layout for explaining the main components of a semiconductor memory device 1 according to some embodiments. FIG. 2 is a layout illustrating a portion of the cell region CR arranged adjacent to the peripheral region PR in the semiconductor memory device 1 of FIG. 1 and is provided for convenience of description.

Referring to FIG. 2, the semiconductor memory device 1 may include the cell region CR and the peripheral region PR. The semiconductor memory device 1 may include a plurality of memory active regions ACT formed in the cell region CR and a plurality of logic active regions ACTP formed in the peripheral region PR. The cell region CR may include the cell block SCB shown in FIG. 1 in which the plurality of semiconductor memory cells is disposed, and the peripheral region PR may be the peripheral region PR shown in FIG. 1 including the main peripheral region PRR and the sub-peripheral region SPR. The boundary region BR may be between the cell region CR and the peripheral region PR.

In some embodiments, the memory active regions ACT disposed in the memory cell region CR may be regularly arranged to have a long axis in a diagonal direction with respect to a first horizontal direction (e.g., an X direction) and a second horizontal direction (e.g., a Y direction). However, the inventive concept is not limited thereto, and in some embodiments, the memory active regions ACT may be regularly arranged to have the long axis in the X direction or in the Y direction. In addition, in some embodiments, the memory active regions ACT may be arranged side by side in the X or Y direction or may be arranged in a zigzag manner in the X or Y direction.

Each active memory region ACT in the plurality of memory active regions ACT formed in the cell region CR may be defined by a device isolation insulating layer 14. The device isolation insulating layer 14 may be an insulating layer around each memory active region ACT. The insulating layer may be formed in a trench around each memory active region ACT. The trench may be formed using a shallow trench isolation (STI) process and the trench may be filled with the insulating layer in order to electrically separate memory active regions ACT from each other. In addition, the plurality of logic active regions ACTP formed in the peripheral region PR may be defined by a device isolation insulating layer 54. The device isolation insulating layer 54 may be a device insulating layer around each logic active region ACTP. The insulating layer may be formed in a trench around each log active region ACTP. The trench may be formed in the semiconductor substrate around each logic active region ACTP and the trench may be with the insulating layer.

The inventive concept may be applied to a case where each of the memory active regions ACT has an elongated shape with the long axis and a short axis, and a spacing between the memory active regions ACT that are adjacent in the long axis direction is different from a spacing between the memory active regions ACT that are adjacent in the short axis direction. Hereinafter, the description will be made with reference to embodiments in which the memory active regions ACT may be regularly arranged to have the long axis in the diagonal direction with respect to the first horizontal direction (the X direction) and the second horizontal direction (the Y direction), and the spacing between the adjacent memory active regions ACT in the long axis direction is greater than the spacing between the adjacent memory active regions ACT in the short axis direction.

Referring again to FIG. 2, each memory active region ACT may have a long axis length L1 and a short axis length L2 (wherein, L1>L2). A distance between the memory active regions ACT that are adjacent to each other in the short axis direction of the memory active regions ACT may be indicated as D1, and a distance between the memory active regions ACT that are adjacent to each other in the long axis direction thereof may be indicated as D2 (wherein, D2>D1). In addition, a distance in the X direction between each of the logic active regions ACTP formed in the peripheral region PR may be indicated as D3, and a distance between the outermost memory active region ACT facing toward the peripheral region PR among the plurality of memory active regions ACT in the cell region CR and the innermost logic active region ACTP facing toward the cell region CR among the plurality of logic active regions ACTP in the peripheral region PR may be indicated as D4.

A distance D5′ may indicate the distance (i.e., D5′=2D1+L2) between one memory active region ACT and the next but one memory active region ACT in the short axis direction of the memory active region ACT. The phrase “next but one” indicates the item after the next item. For example, given three items in order from first to third, and referring to the first item, the next item is the second item and the next but one item is the third item. In addition, since the memory active regions ACT are formed in the diagonal direction with an angle θ with respect to the first horizontal direction (the X direction), a distance D5 may indicate the distance (i.e., D5′=D5×sin θ) between one memory active region ACT and the next but one memory active region ACT in the first horizontal direction. Considering that the memory active regions ACT are formed in the diagonal direction with the angle θ with respect to the first horizontal direction (the X direction), a distance D6 may indicate the distance (i.e., D1=D6×sin θ) between one memory active region ACT and the adjacent memory active region ACT in the first horizontal direction.

In some embodiments, the semiconductor memory device 1 may be a dynamic random access memory (DRAM) device. For the convenience of description, FIG. 2 is a simplified schematic that shows only the arrangement of a portion of the plurality of memory active regions ACT which are formed in the cell region CR near the peripheral region PR and a portion of the plurality of logic active regions ACTP formed in the peripheral region PR.

Although not specifically shown, in a case of the DRAM device, a plurality of word lines WL may extend parallel to each other in the first horizontal direction (the X direction) across the plurality of memory active regions ACT in the memory cell region CR. On the plurality of word lines WL, a plurality of bit lines BL (not shown) may extend parallel to each other in the second horizontal direction (the Y direction) that intersects the first horizontal direction (the X direction). The plurality of bit lines BL may be connected to the plurality of memory active regions ACT through direct contacts DCs (not shown).

In some embodiments, a plurality of buried contacts BC (not shown) may be formed between adjacent bit lines BL among the plurality of bit lines BL. In some embodiments, the plurality of buried contacts BC may be arranged in a line in the first horizontal direction (the X direction) and the second horizontal direction (the Y direction), respectively.

A plurality of landing pads LPs (not shown) may be formed on the plurality of buried contacts BC. The plurality of landing pads LPs may be arranged to at least partially overlap the plurality of buried contacts BC. In some embodiments, the plurality of landing pads LPs may extend to an upper portion of any one of the adjacent bit lines BL.

A plurality of storage nodes SN (not shown) may be formed on the plurality of landing pads LPs. The plurality of storage nodes SN may be formed on the upper portion of the plurality of bit lines BL. Each of the plurality of storage nodes SN may be a lower electrode of a plurality of capacitors (not shown). The storage node SN may be connected to the memory active region ACT through the landing pad LP and the buried contact BC.

A plurality of gate line patterns GLP (not shown) may be arranged on the logic active region ACTP in the peripheral region PR. The plurality of gate line patterns GLP may extend parallel to each other in the first horizontal direction (the X direction) on the logic active region ACTP.

For write and read operations of DRAM, the plurality of word lines WL that extend parallel to each other in the first horizontal direction (the X direction) across the plurality of memory active regions ACT in the memory cell region may be driven by a sub-wordline driver SWLD formed in the peripheral region PR. The sub-wordline driver SWLD may include a P-channel metal oxide semiconductor (PMOS) transistor and an N-channel metal oxide semiconductor (NMOS) transistor.

In some embodiments, the sub-wordline driver SWLD may be formed in the plurality of logic active regions ACTP to drive the plurality of word lines WL extending from the cell region CR in the X direction and may include a PMOS device. For example, the PMOS device may include a PMOS transistor. Such sub-wordline drivers may be referred to as a PMOS sub-wordline driver (PSWD).

In general, a device isolation process, such as the STI process, may be used to electrically isolate adjacent devices in the semiconductor memory device. Specifically, the STI process may be used to electrically isolate the memory active regions ACT formed in the cell region CR from each other and the logic active regions ACTP formed in the peripheral region PR from each other, so that a device isolation insulating layer may be formed around each of the memory active regions ACT and each of the logic active regions ACTP. The device isolation insulating layer may be formed by forming a trench in the semiconductor substrate around each of the memory active regions ACT and the logic active regions ACTP, sequentially forming a thin oxide layer and a liner nitride layer in the trench, and forming an insulating layer for isolating devices, for example, an oxide layer thereon to fill the trench.

The oxide layer used for the insulating layer for isolating devices may have a tensile stress, which may cause a compressive stress to be applied to active regions surrounded by the device isolation insulating layer. In a case of an NMOS device, when a channel in the active region undergoes the compressive stress, the mobility of electrons may decrease and the operation speed of the NMOS device may decrease. A nitride layer used in the device isolation insulating layer may play a role in relieving, countering, or preventing the stress generated by the oxide layer. Accordingly, in an area where the NMOS device is formed, the nitride layer in the device isolation insulating may play an important role in reducing stress.

In the area where the PMOS device is formed, according to the characteristics of the PMOS transistor, when the PMOS transistor is turned on, electron hole pairs (EHP), which are hot carriers, may be generated and electrons among the electron hole pairs may be trapped in the liner nitride layer. Hot electron induced punch through (HEIP) may be induced by electrons trapped in the liner nitride layer and holes may be induced at an edge of a channel of the active region of the PMOS transistor by electrons trapped in the liner nitride layer. Thus, even when the PMOS transistor is in the off state, deterioration of off characteristics may occur, causing the current to rise. In order to alleviate this problem in the area where the PMOS device is formed, the forming of the nitride layer may be skipped when forming the device isolation insulating layer, or a nitride layer already formed in the device isolation insulating layer may be removed. Alternatively, a nitride layer formed in the device isolation insulating layer may be formed in a manner that it should not be a factor that deteriorates the operation characteristics of the PMOS device.

When the spacing between the logic active regions is narrow in the peripheral region where the PMOS device is formed, the nitride layer may remain within the device isolation insulating layer during an STI process for forming the device isolation insulating layer that defines the logic active regions. In this case, as described above, the operation characteristics of the PMOS device may deteriorate, thereby lowering the reliability of the semiconductor memory device.

On the other hand, when the spacing between the logic active regions is wide in the peripheral region where the PMOS device is formed, the nitride layer may not be formed within the device isolation insulating layer during the STI process for forming the device isolation insulating layer that defines the logic active regions. In order to not have the nitride layer in the device isolation insulating layer, the spacing between the logic active regions in the peripheral region previously was formed to be much greater than the spacing between the memory active regions in the cell region. However, while the problem of deteriorating the operation characteristics of the PMOS device as described above may not occur, the size of the semiconductor memory device may be increased by the widened spacing, which runs counter to the trend of miniaturization of the semiconductor memory device.

Considering the problems as described above, embodiments of the inventive concept may provide semiconductor memory devices and methods of manufacturing the same, in which a nitride layer is not present in a device isolation insulating layer that isolates logic active regions from each other in a peripheral region where a PMOS device is formed.

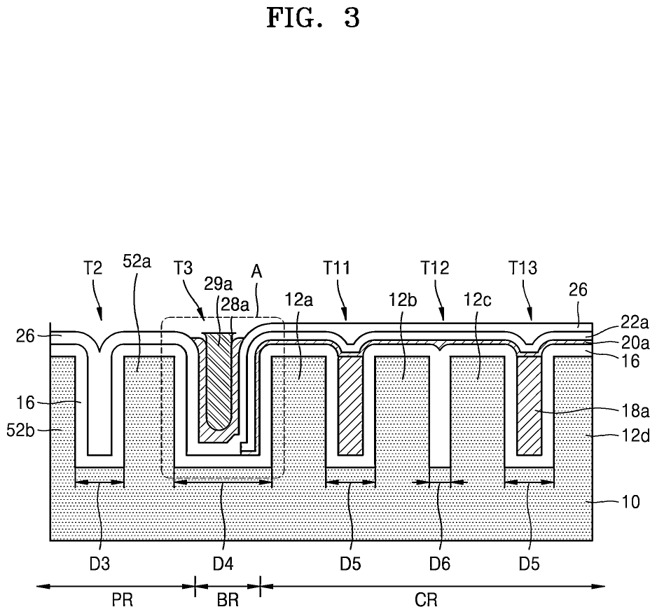

FIG. 3 is a cross-sectional view showing a semiconductor memory device according to some embodiments. FIG. 3 is a cross-sectional view taken along line A-A′ of FIG. 2.

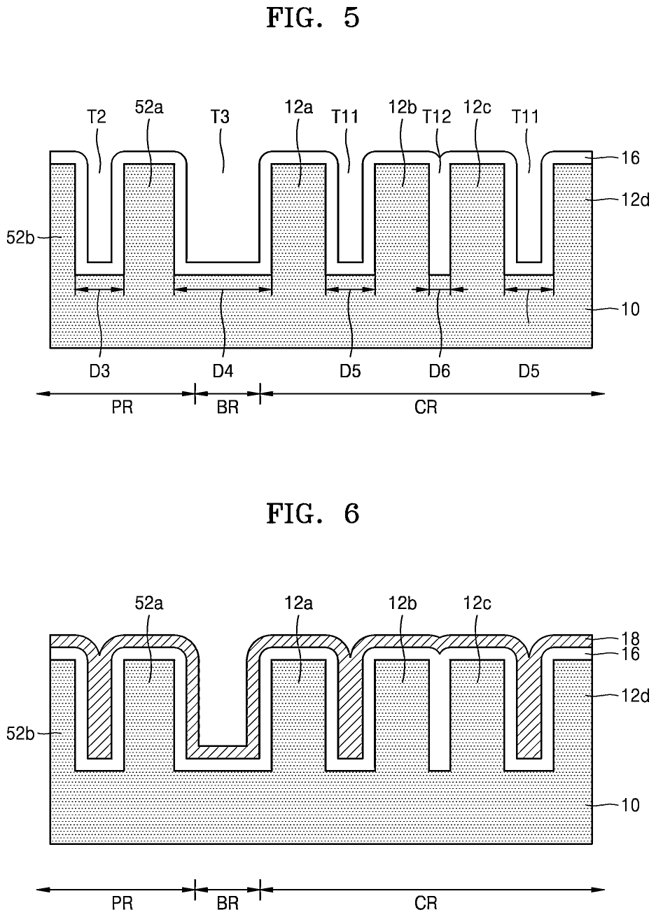

Referring to FIG. 3 together with FIG. 2, the plurality of active regions may be formed at an upper portion of a semiconductor substrate 10. The semiconductor substrate 10 may have a cell portion corresponding to the cell region, a peripheral portion corresponding to the peripheral region, and a boundary portion corresponding to the boundary region. The plurality of memory active regions formed in the cell region CR may include a first memory active region 12a, a second memory active region 12b, a third memory active region 12c, and a fourth memory active region 12d sequentially formed toward the inside (e.g., a center) of the cell region. The plurality of logic active regions formed in the peripheral region PR may include a first logic active region 52a and a second logic active region 52b sequentially formed towards the outside of the semiconductor memory device 1. A first trench (T11 and T12 in FIG. 5) may refer to a trench surrounding the memory active regions in the cell region CR, a second trench (T2 in FIG. 5) may refer to a trench surrounding the logic active regions in the peripheral region PR, and a third trench (T3 in FIG. 5) may refer to a trench formed between the cell region CR and the peripheral region PR. In some embodiments, the cell region CR may be a NMOS region where semiconductor memory cells are formed and the NMOS transistors are mainly formed, but is not limited thereto. On the other hand, the peripheral region PR may be a PMOS region where at least a PMOS device, for example, PMOS transistors are formed.

The device isolation insulating layer 14 may be formed in the first trench T11. A portion of the first trench T11 between the first memory active region 12a and the second memory active region 12b and between the third memory active region 12c and the fourth memory active region 12d may include a first nitride insulating layer 18a. The portion of the first trench T11 between the first memory active region 12a and the second memory active region 12b and between the third memory active region 12c and the fourth memory active region 12d as shown in FIG. 3 may be a portion of the first trench T11 that is formed between memory cell active regions that are adjacent along the long axis direction of the memory cell active regions, as shown in FIG. 2. A portion of the device isolation insulating layer that is formed in the first trench T12 between the second memory active region 12b and the third memory active region 12c may exclude the first nitride insulating layer. The portion of the first trench T12 between the second memory active region 12b and the third memory active region 12c may be a portion of the first trench T12 formed between the memory cell active regions that are adjacent along the short axis direction of the memory cell active region, as shown in FIG. 2.

According to some embodiments, the first nitride insulating layer 18a may not exist in a device isolation insulating layer formed in the second trench T2 between the first logic active region 52a and the second logic active region 52b in the peripheral region PR. Therefore, the deterioration of the operation characteristics of the PMOS device due to the first nitride insulating layer 18a as described above may not occur in the first logic active region 52a and the second logic active region 52b, which are the PMOS region.

According to some embodiments, the distance D3 in the X direction between the plurality of logic active regions ACTP formed in the peripheral region PR (e.g., the distance D3 between the first logic active region 52a and the second logic active region 52b) may be substantially the same as the distance D2, which is the distance between memory active regions in the long axis direction of the memory active regions formed in the cell region CR.

The phrase “substantially the same distance” means that the difference between the distance D3 and the distance D2 is about 20% or less, such as preferably about 10% or less, preferably about 5% or less, preferably about 2% or less, or preferably about 1% or less. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning unless the context or other statements indicate otherwise.

As described above with reference to FIG. 2, the distance D5 is the distance between the first memory active region 12a and the second memory active region 12b, which are next but one adjacent in the short axis direction, in the first horizontal direction (i.e., D5′=D5×sin θ, wherein D5′=2D1+L2). The distance D5 may be not necessarily the same as the distance D5′. However, since the distance D5 is the distance between the next but one adjacent memory active regions in the short axis direction, the distance D5 may be the same as or similar to the distance D2. In some embodiments, the distance D5 may also be “substantially the same” as the distance D2. The distance D6 may be the same as or similar to the distance D1 depending on the angle θ and is related using the formula D1=D6×sin θ).

According to some embodiments, although the distance D3 in the X direction between the adjacent logic active regions (e.g., the distance D3 between the first logic active region 52a and the second logic active region 52b) may be substantially the same as the distance D5 in the X direction between the adjacent memory active regions as viewed in the cross-section of FIG. 3 (e.g., the distance D5 between a first memory active region 12a and a second memory active region 12b), the first nitride insulating layer 18a may be formed in the device isolation insulating layer in the first trench T11 disposed in the cell region CR, but the first nitride insulating layer 18a may not be formed in the device isolation insulating layer in the second trench T2 disposed in the peripheral region PR. Therefore, even though the spacing between the logic active regions in the peripheral region PR is reduced to the spacing between the memory active regions in the cell region CR, the first nitride insulating layer 18a is not formed in the device isolation insulating layer in the second trench T2 in the peripheral region PR, so the entire size of the semiconductor memory device 1 in the X direction may decrease without the deterioration of the operation characteristics of the PMOS device. For the same reason, the entire size of the semiconductor memory device 1 in the Y direction may decrease.

The semiconductor substrate 10 may be formed of and/or include, for example, silicon (Si), crystalline Si, polycrystalline Si, or amorphous Si. In some embodiments, the semiconductor substrate 10 may be formed of and/or include a semiconductor element such as germanium (Ge) and at least one compound semiconductor selected from SiGe, SiC, GaAs, InAs, and InP. In some embodiments, the semiconductor substrate 10 may have a silicon on insulator (SOI) structure. For example, the semiconductor substrate 10 may include a buried oxide (BOX) layer. The semiconductor substrate 10 may include a conductive region, for example, an impurity-doped well, or an impurity-doped structure.

The device isolation insulating layers respectively formed in the first trench T11 and T12, the second trench T2, and the third trench T3 may be formed in different shapes and/or configurations and portions of the device isolation insulating layers may be formed of and/or include different materials. In general, the device isolation insulating layer may include at least one of silicon oxide, silicon nitride, or silicon oxynitride, for example. The device isolation insulating layer may include a single layer consisting of one kind of insulating layer, a double layer consisting of two kinds of insulating layers, or a multiple layer consisting of at least three kinds of insulating layers.

A first portion of the device isolation insulating layer formed in the first trench T11 between the memory active regions in the long axis direction of the memory active regions, for example, between the first memory active region 12a and the second memory active region 12b (or between the third memory active region 12c and the fourth memory active region 12d), may include a first insulating layer 16, the first nitride insulating layer 18a, a second insulating layer 20a, a third insulating layer 22a, and a fourth insulating layer 26 that are sequentially stacked. The phrase sequentially stacked indicates that the elements are stacked on one another in the given order. In some embodiments, the first insulating layer 16 may include an oxide insulating layer, such as for example, a silicon oxide insulating layer, but is not limited thereto. The first nitride insulating layer 18a may include, for example, a silicon nitride insulating layer, but is not limited thereto. The second insulating layer 20a may include, for example, a nitride insulating layer, or a silicon nitride insulating layer, but is not limited thereto. The third insulating layer 22a may include, for example, an oxide insulating layer, or a silicon oxide insulating layer, but is not limited thereto. The fourth insulating layer 26 may include, for example, an oxide insulating layer, or a silicon oxide insulating layer, but is not limited thereto.

A second portion of the device isolation insulating layer formed in the first trench T12 between the memory active regions in the short axis direction of the memory active regions, for example, between the second memory active region 12b and the third memory active region 12c, may include the first insulating layer 16, the second insulating layer 20a, the third insulating layer 22a, and the fourth insulating layer 26 that are sequentially stacked. In particular, the device isolation insulating layer formed in the second portion of the first trench T12 compared to the device isolation insulting layer in the first portion of the first trench T11 does not include (e.g., omits) the first nitride insulating layer 18a, and most of the second portion of the first trench T12 may be filled with the first insulating layer 16.

The device isolation insulating layer formed in the second trench T2 between the logic active regions in the peripheral region PR, for example, between the first logic active region 52a and the second logic active region 52b, may include the first insulating layer 16 and the fourth insulating layer 26 that are sequentially stacked. In particular, the device isolation insulating layer in the second trench T2 compared to the first portion of the device isolation layer in the first trench may not include (e.g., omit) the first nitride insulating layer 18a included in the first portion of the first trench T11, and most of the remainder of the second trench T2 may be filled with the fourth insulating layer 26.

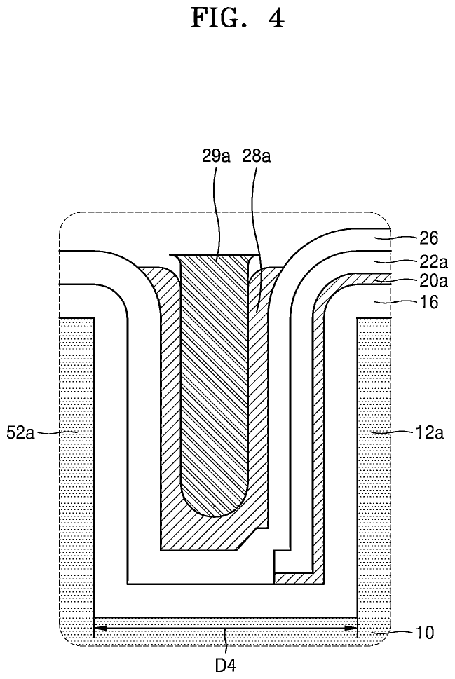

The device isolation insulating layer formed in the third trench T3 of the boundary region BR is asymmetrically formed, as shown in FIG. 3 and FIG. 4, which is an enlarged cross-sectional view of the ‘A’ part of FIG. 3. Specifically, the device isolation insulating layer formed on a side of the first memory active region 12a, which is the outermost memory active region adjacent to the boundary region BR among the memory active regions, may include the first insulating layer 16, the second insulating layer 20a, the third insulating layer 22a, and the fourth insulating layer 26 and they are sequentially stacked along a sidewall of the first memory active region 12a. The device isolation insulating layer formed on a side of the first logic active region 52a, which is the innermost logic active region adjacent to the boundary region BR among the logic active regions, may include the first insulating layer 16 and the fourth insulating layer 26 and they are sequentially stacked along a sidewall of the first logic active region 52a.

In addition, the device isolation insulating layer formed in the third trench T3 of the boundary region BR may include a fifth insulating layer 28a and a sixth insulating layer 29a on the fourth insulating layer 26. The fifth insulating layer 28a may include, for example, a nitride insulating layer, or a silicon nitride insulating layer, but is not limited thereto. The sixth insulating layer 29a may be formed of and/or include an oxide insulating layer, such as for example, a polysilazane layer having the trade name of Tonen SilaZene (TOSZ®), but is not limited thereto.

As shown in FIG. 4, the second insulating layer 20a and the third insulating layer 22a in the device isolation insulating layer that is formed on the side of the first memory active region 12a may protrude in the horizontal direction (i.e., the X direction) toward a central region of the third trench T3 in a tail shape. For example, a lower end of the of the second insulating layer 20a and the third insulating layer 22a may extend horizontally from the sidewall of the third trench T3 relative to the remaining portion of the second insulating layer 20a and the third insulating layer 22a.

According to some embodiments, the deterioration of the operation characteristics of the PMOS device due to a nitride insulating layer as described above may not occur in the first logic active region 52a and the second logic active region 52b, which are PMOS regions. In addition, according to some embodiments, even though the spacing between the logic active regions in the peripheral region PR is reduced to the spacing between the memory active regions in the cell region CR, the first nitride insulating layer 18a is not formed in the device isolation insulating layer in the second trench T2 in the peripheral region PR, so the entire size in the X and Y directions of the semiconductor memory device 1 may decrease without the deterioration of the operation characteristics of the PMOS device.

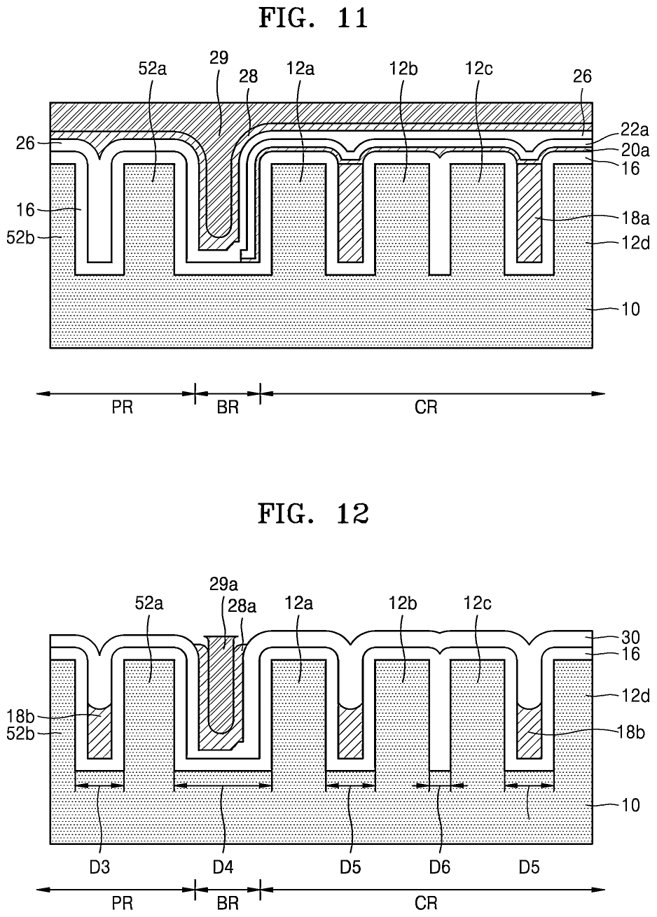

FIGS. 5 to 11 are cross-sectional views sequentially showing states of a semiconductor memory device during a method of manufacturing the semiconductor memory device according to some embodiments. FIGS. 5 to 11 are cross-sectional views taken along a line A-A′ of FIG. 2. FIG. 3 is a cross-sectional view after performing a step of FIG. 11.

Referring to FIG. 5 together with FIG. 2, the trenches, T11, T12, T2, and T3 may be formed in an upper portion of the semiconductor substrate 10, by etching portions of the semiconductor substrate 10 through a photolithography process using a mask (not shown). The trenches T11, T12, T2, T3 are shown as separated from each other in the cross-sectional view of FIG. 5, but are connected to each other in a plan view (e.g., portions of the trenches may extend in a horizontal direction between the trenches in other cross-sections). As a result of forming the trenches T11, T12, T2, and T3, the plurality of memory active regions ACT and the plurality of logic active regions ACTP may be formed in the upper portion of the semiconductor substrate 10. The plurality of memory active regions ACT formed in the cell region CR may include the first memory active region 12a, the second memory active region 12b, the third memory active region 12c, and the fourth memory active region 12d sequentially formed toward the inside of the cell region CR. The plurality of logic active regions ACTP formed in the peripheral region PR may include the first logic active region 52a and the second logic active region 52b sequentially formed towards the outside of the semiconductor memory device 1. In addition, the trenches formed in the cell region CR may be identified as the first trenches T11 and T12, the trench formed in the peripheral region PR may be identified as the second trench T2, and the trench formed in the boundary region BR may be identified as the third trench T3.

In some embodiments, the cell region CR may be an NMOS region where semiconductor memory cells are formed, and NMOS transistors may be mainly formed, but is not limited thereto. On the other hand, the peripheral region PR may be a PMOS region where at least a PMOS device, for example, PMOS transistors are formed.

According to some embodiments, the distance D3 between the first logic active region 52a and the second logic active region 52b may be substantially the same as the distance D2 in the long axis direction between the memory active regions that are adjacent to each other in along the long axis direction of the plurality of memory active regions formed in the cell region CR. As described above with respect to FIGS. 2 and 3, the difference between the distance D3 and the distance D2 may be in the range of about 20% or less, such as preferably about 10% or less, preferably about 5% or less, preferably about 2% or less, or preferably about 1% or less. In addition, the distance D5 indicates the distance between the first memory active region 12a and the second memory active region 12b (i.e., D5′=D5×sin θ, wherein D5′=2D1+L2, θ is an inclined angle with respect to the horizontal direction) and the distance D5 may not be the same as the distance D2. The distance D5 is the distance between the memory active regions in the first horizontal direction and is dependent on the distance between adjacent but one memory active regions of the memory active regions and the distance D5 may be the same as or similar to the distance D2. In some embodiments, the distance D5 may also be “substantially the same” as the distance D2. Under the same premise as above, the distance D6 may be the same as or similar to the distance D1 and is related by the formula D1 =D6×sin θ).

Subsequently, the first insulating layer 16 may be formed on an exposed surface of the semiconductor substrate 10 in which the plurality of memory active region and the plurality of logic active region are formed. The first insulating layer 16 may be formed by performing a physical vapor deposition (PVD) process or a chemical vapor deposition (CVD) process. Specifically, known deposition techniques, such as thermal evaporation method, sputtering deposition method, atmosphere CVD (APCVD) method, low pressure CVD (LPCVD) method, plasma enhanced CVD (PECVD) method, high-density plasma CVD (HDPCVD) method, metal organic CVD (MOCVD) method, and atomic layer deposition (ALD) method, or the like, may be used for the formation of the first insulating layer 16. In some embodiments, the ALD method may be used.

The first insulating layer 16 may be formed differently depending on the size of the trench, for example, the horizontal distance of the trench or the width of the trench. Specifically, in the first portion of the first trench T11 between the first memory active region 12a and the second memory active region 12b and between the third memory active region 12c and the fourth memory active region 12d, in the second trench T2 between the first logic active region 52a and the second logic active region 52b, and in the third trench T3 in the boundary region BR, the first insulating layer 16 may be formed along the bottom and sidewalls of the trenches thereof without completely filling the trenches thereof. However, the second portion of the first trench T12 between the second memory active region 12b and the third memory active region 12c that has a narrow width of the trench may be completely filled with the first insulating layer 16. The first insulating layer 16 may include an oxide-based insulating layer, for example, a silicon oxide insulating layer, and is not limited thereto.

Referring to FIG. 6, the first nitride insulating layer 18 may be formed on the entire surface of the semiconductor substrate 10 on which the first insulating layer 16 is formed. The first nitride insulating layer 18 may be formed differently depending on the size of the trench, for example, the horizontal distance of the trench or the width of the trench. Specifically, the first portion of the first trench T11 between the first memory active region 12a and the second memory active region 12b, the first portion of the first trench T11 between the third memory active region 12c and the fourth memory active region 12d, and the second trench T2 between the first logic active region 52a and the second logic active region 52b may be completely filled with the first nitride insulating layer 18. On the other hand, the first nitride insulating layer 18 may be formed along the bottom and sidewalls of the third trench T3 in the boundary region BR, which has a relatively large size, without completely filling the third trench T3. On the other hand, in the second portion of the first trench T12 between the second memory active region 12b and the third memory active region 12c where the width of the trench T12 is relatively small and which may have been completely filled with the first insulating layer 16, the first nitride insulating layer 18 may not be formed. The first nitride insulating layer 18 may include a nitride-based insulating layer, for example a silicon nitride insulating layer, and is not limited thereto. The first nitride insulating layer 18 may have an etch selectivity with respect to the first insulating layer 16 depending on etching conditions.

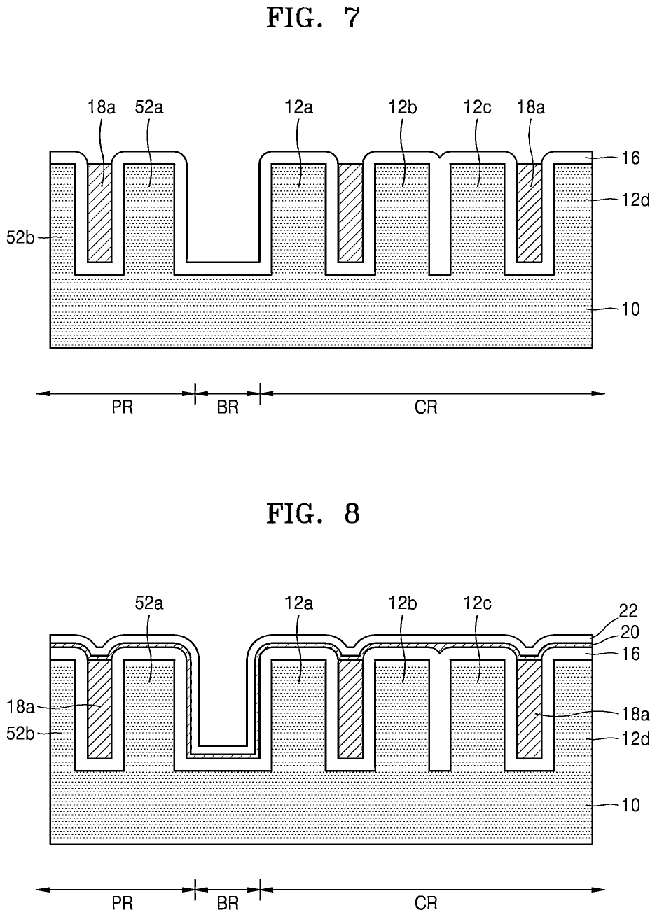

Referring to FIG. 7, an etching process may be performed on the first nitride insulating layer 18 to remove a portion of the first nitride insulating layer 18. The etching process may be performed using a dry etching method or a wet etching method. For example, a chemical etching method using an etchant, such as a strip process, or known dry etching method, such as a plasma etching method, a sputtering etching method, a reactive ion etching (RIE) method, and the like, may be used for the etching process. As a result of the etching process, the first nitride insulating layer 18 may remain in the first portion of the first trench T11 between the first memory active region 12a and the second memory active region 12b, the first portion of the first trench T11 between the third memory active region 12c and the fourth memory active region 12d, and the second trench T2 between the first logic active region 52a and the second logic active region 52b. On the other hand, in the third trench T3 of the boundary region BR where the size of the trench is relatively large, an exposure region of the first nitride insulating layer 18 exposed to the etching environment is relatively large, so the first nitride insulating layer 18 may be completely removed.

Referring to FIG. 8, the second insulating layer 20 may be formed on an entire exposed surface of the semiconductor substrate 10 in the state shown in FIG. 7. The second insulating layer 20 may include a nitride-based insulating layer, for example a silicon nitride insulating layer, and is not limited thereto. The second insulating layer 20 may be formed to be relatively thinner than the first nitride insulating layer 18. The second insulating layer 20 may have an etch selectivity with respect to the first nitride insulating layer 18 depending on etching conditions. Subsequently, the third insulating layer 22 may be formed on the second insulating layer 20. The third insulating layer 22 may have an etch selectivity with respect to the second insulating layer 20 depending on etching conditions. The third insulating layer 22 may include an oxide-based insulating layer, such as a silicon oxide insulating layer. The third insulating layer 22 may be a buffer oxide insulating layer that acts as a buffer when removing the second insulating layer 20, which is a nitride-based insulating layer in a subsequent process.

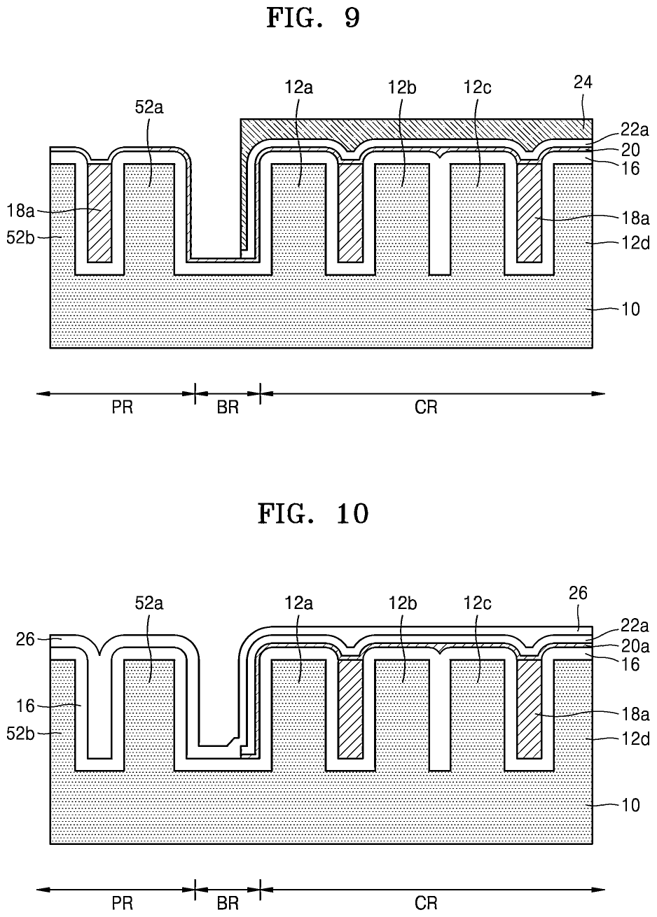

Referring to FIG. 9, a mask pattern 24 may be formed on a portion of the exposed surface of the semiconductor substrate 10 in the state shown in FIG. 8, in which the mask pattern 24 may cover the cell region CR and a portion of the boundary region BR and may selectively expose the peripheral region PR and another portion of the boundary region BR. The mask pattern 24 may be formed using the photolithography technology using photoresist material. Subsequently, using the mask pattern 24 as an etch mask, the third insulating layer 22, which acts as a buffer layer, may be selectively removed in the peripheral region PR and the another portion of the boundary region BR, so as to form a third insulating layer 22a. As a result, a portion of the second insulating layer 20 may be exposed in the peripheral region PR and the another portion of the boundary region BR.

Referring to FIG. 10, the mask pattern 24 may be removed. The removal of the mask pattern 24 may be performed through a dry strip process (or an ashing process), for example. In the dry strip process, for example, oxygen (O₂) plasma or SF₆/O₂ plasma may be used, in which the oxygen plasma may break connection links of organic matter from the photoresist material and even break benzene rings to remove the photoresist material. After the dry strip process, a cleaning process may be performed to remove the mask pattern 24.

Subsequently, referring to FIG. 10, by removing the mask pattern 24, the third insulating layer 22a which was previously covered by the mask pattern 24 may be exposed and have the same pattern as the now removed mask pattern 24. Subsequently, using the exposed third insulating layer 22a as an etch mask, a portion of the second insulating layer 20 may be etched and removed in the peripheral region PR and the another portion of the boundary region BR so as to form a second insulating layer 20a. Subsequently, the first nitride insulating layer 18a remaining in the second trench T2 of the peripheral region PR may be removed. Preferably, the first nitride insulating layer 18a remaining in the second trench T2 may be completely removed. In some embodiments, as long as any remainder of the first nitride insulating layer 18a does not cause the operation characteristics of the PMOS device to be deteriorated in the PMOS region formed in the first logic active region 52a and the second logic active region 52b, a portion of the first nitride insulating layer 18a may remain near the bottom of the second trench T2.

Subsequently, after removing the third insulating layer 22a and the first nitride insulating layer 18a from the peripheral region PR and the another portion of the boundary region BR, the fourth insulating layer 26 may be formed on the entire surface of the semiconductor substrate 10. The fourth insulating layer 26 may have an etch selectivity with respect to the third insulating layer 22a depending on etching conditions. The fourth insulating layer 26 may be formed on the third insulating layer 22a in the cell region CR and the portion of the boundary region BR, and may be formed on the first insulating layer 16 in the peripheral region PR and the another portion of the boundary region BR. At this time, a remaining portion of the second trench T2 may be completely filled with the fourth insulating layer 26. The fourth insulating layer 26 may be formed using various deposition technologies, for example, the ALD method. The fourth insulating layer 26 may have an etch selectivity with respect to the third insulating layer 22a depending on etching conditions. The fourth insulating layer 26 may include an oxide-based insulating layer, such as for example, a silicon oxide insulating layer, and is not limited thereto.

The device isolation insulating layers formed on left and right sides of the third trench T3 in the boundary region BR may be formed asymmetrically. Specifically, on a side wall of the third trench T3 contacting the sidewall of the first memory active region 12a (i.e., the right side wall in the figures), the first insulating layer 16, the second insulating layer 20a, the third insulating layer 22a, and the fourth insulating layer 26 may be sequentially stacked. However, on a side wall of the third trench T3 contacting the sidewall of the first logic active region 52a (i.e., the left sidewall in the figures), the first insulating layer 16 and the fourth insulating layer 26 may be sequentially stacked without the second insulating layer 20a and the third insulating layer 22a. In addition, the second insulating layer 20a and the third insulating layer 22a formed on the right sidewall of the third trench T3 may protrude toward the central region of the third trench T3 with a tail shape. The degree of protruding may depend on a boundary of the mask pattern 24 in FIG. 9. In some embodiments, according to a boundary position of the mask pattern 24, the second insulating layer 20a and the third insulating layer 22a may be formed parallel to and along the sidewall of the first memory active region 12a without any protruding portion. In this case where the protruding portion is not present, a portion of the second insulating layer 20a formed below the third insulating layer 22a may protrude horizontally toward the central region of the third trench T3 by a length corresponding to a thickness of the third insulating layer 22a.

Referring to FIG. 11, a fifth insulating layer 28 may be formed on the surface of the semiconductor substrate 10 in the state shown in FIG. 10, and then a sixth insulating layer 29 may be formed on the fifth insulating layer 28. The fifth insulating layer 28 may have an etch selectivity with respect to the fourth insulating layer 26, depending on etching conditions. The sixth insulating layer 29 may have an etch selectivity with respect to the fifth insulating layer 28 and the fourth insulating layer 27, depending on etching conditions. The fifth insulating layer 28 may include a nitride-based insulating layer, for example, a silicon nitride insulating layer, and is not limited thereto. The sixth insulating layer 29 may include an oxide-based insulating layer, for example, a polysilazane layer which may be identified by the trade name TOSZ®, but is not limited thereto. The sixth insulating layer 29 may completely fill the third trench T3 in the boundary region BR.

Subsequently, referring to FIG. 3, portions of the sixth insulating layer 29 and the fifth insulating layer 28 may be removed from the result of FIG. 11 through an appropriate etching process. Depending on etching conditions, the sixth insulating layer 29 may have an etch selectivity with respect to the fifth insulating layer 28 and the fourth insulating layer 26 and the fifth insulating layer 28 may have an etch selectivity with respect to the fourth insulating layer 26, so the sixth insulating layer 29 and the fifth insulating layer 28 may remain only in the third trench T3 in the boundary region BR while completely filling the third trench T3.

FIG. 12 is a cross-sectional view showing a semiconductor memory device according to some embodiments. FIG. 12 is a cross-sectional view taken along a line A-A′ of FIG. 2. Descriptions that may be redundant with or overlap the descriptions of embodiments related to FIGS. 3 to 11 may be briefly described or omitted.

Referring to FIG. 12 together with FIG. 2, in the cell region CR, the plurality of memory active regions formed on the upper portion of the semiconductor substrate 10 may include the first memory active region 12a, the second memory active region 12b, the third memory active region 12c, and the fourth memory active region 12d sequentially formed toward the inside of the cell region CR. In the peripheral region PR, the first logic active region 52a and the second logic active region 52b may be sequentially formed towards the outside of the semiconductor memory device. Although not indicated by reference numbers in FIG. 12, the first trenches (T11 and T12 in FIG. 5), the second trench (T2 in FIG. 5) and the third trench (T3 in FIG. 5) may be formed in positions corresponding to those in FIG. 5, respectively. In addition, the distances D3, D4, D5, and D6 are the same as the distances D3, D4, D5, and D6 shown in FIG. 5. The peripheral region PR may be the PMOS region where at least the PMOS device, for example, the PMOS transistors are formed.

The device isolation insulating layer formed in the first portion of the first trench T11 between the first memory active region 12a and the second memory active region 12b and formed in the first portion of the first trench T11 between the third memory active region 12c and the fourth memory active region 12d may include a first nitride insulating layer 18b having a certain thickness near the bottom of the first trench T11 (e.g., the first nitride insulating layer 18b may not fill the trench completely). In addition, the device isolation insulating layer formed in the trench T2 between the first logic active region 52a and the second logic active region 52b in the peripheral region PR may also include the first nitride insulating layer 18b having a certain thickness near the bottom of the second trench T2, in which the first nitride insulating layer 18b may include the same material as the first nitride insulating layer 18b formed in the first trench T11 and may have approximately the same shape as the first nitride insulating layer 18b formed in the first trench T11.

The thickness of the first nitride insulating layer 18b formed near the bottom of the second trench T2 will be described in detail with reference to FIG. 15. The first nitride insulating layer 18b formed near the bottom of the second trench T2 may be formed to have a thickness in a range that does not deteriorate the operation characteristics of the PMOS devices formed on upper portions of the plurality of logic active regions 52a and 52b.

According to some embodiments, even though the spacing between the logic active regions in the peripheral region PR may be reduced to the spacing between the memory active regions in the cell region CR (e.g., D3≈D5) and the first nitride insulating layer 18b may remain in the device isolation insulating layer in the second trench T2 in the peripheral region PR, the first nitride insulating layer 18b may be formed with a thickness in the range that does not deteriorate the operation characteristics of the PMOS device, so the entire size in the X and Y directions of the semiconductor memory device 1 may decrease.

In some embodiments, the device isolation insulating layers respectively formed in the first trench T11 and T12, the second trench T2, and the third trench T3 may be formed in different shapes.

The device isolation insulating layer formed in the first portion of the first trench T11 between the memory active regions in the long axis direction of the memory active regions, for example, between the first memory active region 12a and the second memory active region 12b (or between the third memory active region 12c and the fourth memory active region 12d), may include the first insulating layer 16, the first nitride insulating layer 18b, and a third insulating layer 30 that are sequentially stacked. In some embodiments, the first insulating layer 16 may include an oxide-based insulating layer, for example, a silicon oxide insulating layer, but is not limited thereto. The first nitride insulating layer 18b may include a nitride-based insulating layer, for example, a silicon nitride insulating layer, and is not limited thereto. The third insulating layer 30 may include, for example, an oxide-based insulating layer, or a silicon oxide insulating layer, but is not limited thereto.

The device isolation insulating layer formed in the second portion of the first trench T12 between the memory active regions in the short axis direction of the memory active regions, for example, between the second memory active region 12b and the third memory active region 12c, may include the first insulating layer 16 and the third insulating layer 30 that are sequentially stacked.

The device isolation insulating layer formed in the second trench T2 between the logic active regions in the peripheral region PR, for example, between the first logic active region 52a and the second logic active region 52b, may include the first insulating layer 16, the first nitride insulating layer 18b, and the third insulating layer 30 that are sequentially stacked in the same manner as the device isolation insulating layer formed in the first trench T11.

The device isolation insulating layer formed in the third trench T3 in the boundary region BR may be formed to be approximately left-right symmetrical, as shown in FIG. 12. Specifically, the device isolation insulating layer formed in the third trench T3 may include the first insulating layer 16 and the third insulating layer 30 sequentially stacked from the bottom of the third trench T3. In addition, in a central portion of the third trench T3, a fifth insulating layer 28a and a sixth insulating layer 29a may be formed on the third insulating layer 30 to completely fill the third trench T3. The fifth insulating layer 28a may be a nitride-based insulating layer, for example, a silicon nitride insulating layer, and the sixth insulating layer 29a may be an oxide-based insulating layer, for example, a TOSZ® layer.

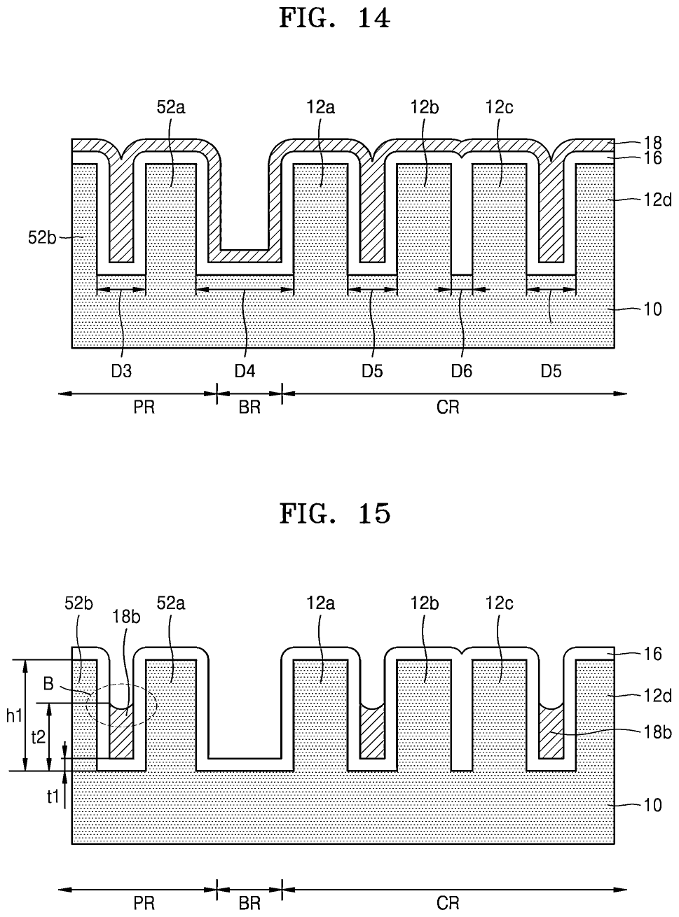

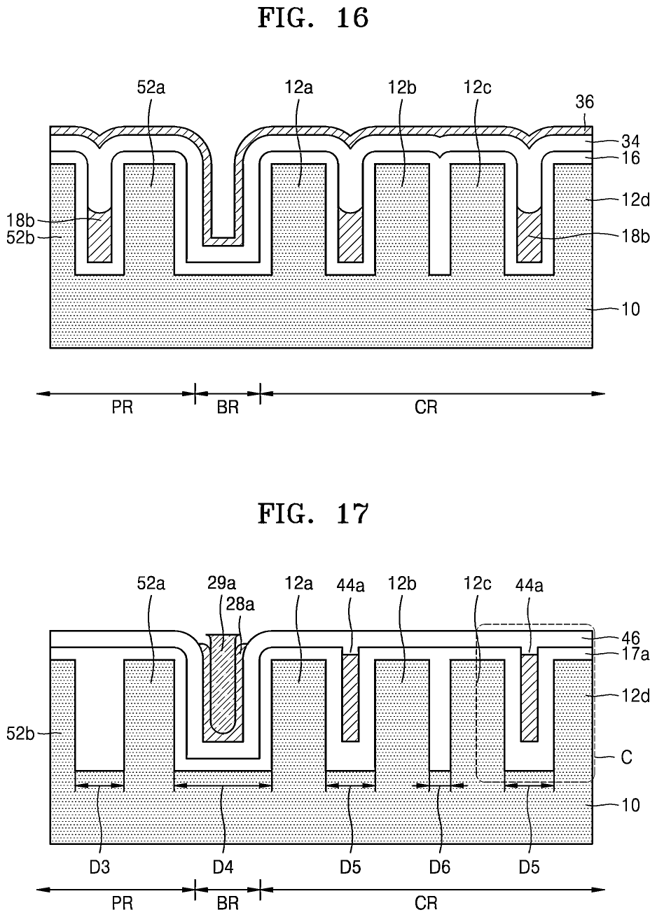

FIGS. 14 to 16 are cross-sectional views sequentially showing states of a semiconductor memory device during a method of manufacturing the semiconductor memory device according to some embodiments. FIGS. 14 to 16 are cross-sectional views taken along a line A-A′ of FIG. 2. FIG. 12 is a cross-sectional view after performing a step of FIG. 16.

Referring to FIG. 14 together with FIG. 2, when the trenches, T11, T12, T2, and T3 may be formed in the upper portion of the semiconductor substrate 10, by etching portions of the semiconductor substrate 10 through the photolithography process, the plurality of memory active regions ACT and the plurality of logic active regions ACTP may be defined. The plurality of memory active regions ACT may include the first memory active region 12a, the second memory active region 12b, the third memory active region 12c, and the fourth memory active region 12d, and the plurality of logic active regions ACTP may include the first logic active region 52a and the second logic active region 52b. The cell region CR may be a NMOS region where semiconductor memory cells are formed and NMOS transistors may be mainly formed, while the peripheral region PR may be a PMOS region where at least PMOS devices, for example PMOS transistors may be formed. The meaning and relative size of the distances D1, D2, D3, D4, D5, and D6 may be the same as those described with reference to FIG. 3. In particular, the distance D3 may be substantially the same as the distance D2 or the distance D5.

Subsequently, referring to FIG. 14, the first insulating layer 16 may be formed on an exposed entire surface of the semiconductor substrate 10 in which the plurality of memory active regions and the plurality of logic active regions are formed. In a first portion of the first trench T11 located between the first memory active region 12a and the second memory active region 12b and between the third memory active region 12c and the fourth memory active region 12d, in the second trench T2 between the first logic active region 52a and the second logic active region 52b, and in the third trench T3 in the boundary region BR, the first insulating layer 16 may be formed along the bottom and sidewalls of the trenches thereof without completely filling the trenches thereof. However, in a second portion of the first trench T12 between the second memory active region 12b and the third memory active region 12c and which has a narrow width, the trench may be completely filled with the first insulating layer 16. The first insulating layer 16 may include an oxide-based insulating layer, for example a silicon oxide insulating layer, and is not limited thereto.

Subsequently, the first nitride insulating layer 18 may be formed on the entire surface of the semiconductor substrate 10 on which the first insulating layer 16 is formed. The first portion of the first trench T11 and the second trench T2 may be completely filled with the first nitride insulating layer 18. On the other hand, in the third trench T3, the first nitride insulating layer 18 may be formed along the bottom and sidewalls of the third trench T3 without completely filling the third trench T3. The first nitride insulating layer 18 may include a nitride-based insulating layer, for example a silicon nitride insulating layer, and is not limited thereto. The first nitride insulating layer 18 may have an etch selectivity with respect to the first insulating layer 16 depending on etching conditions.

Subsequently, referring to FIG. 15, an etching process may be performed on the first nitride insulating layer 18 to remove portions of the first nitride insulating layer 18. The etching process may be performed through the chemical etching method using etchant, for example, the strip process, and is not limited thereto. As a result of the etching process, the first nitride insulating layer 18b may remain in the first portion of the first trench T11 between the first memory active region 12a and the second memory active region 12b and between the third memory active region 12c and the fourth memory active region 12d, and the second trench T2 between the first logic active region 52a and the second logic active region 52b. In the third trench T3 of the boundary region BR, which has a relatively large size of the trench, the first nitride insulating layer 18 may be completely removed.

The first nitride insulating layer 18b remaining in the first portion of the first trench T11 and the second trench T2 between the first logic active region 52a and the second logic active region 52b, may be formed to have a certain height (or thickness) from the bottoms of the first trench T11 and the second trench T2. Specifically, the thickness (or height) (i.e., t2-t1) of the first nitride insulating layer 18b remaining in the second trench T2 may be half of a depth (or height) h1 of the second trench T2 or less. In some embodiments, the height t2 of the first nitride insulating layer 18b from the bottom of the second trench T2 may be half of the depth h1 of the second trench T2 or less. The thickness (or height) of the first nitride insulating layer 18b remaining in the second trench T2 may be determined depending on whether the operation characteristics of the PMOS device deteriorate, in which the PMOS device may be formed on an upper side of the first logic active region 52a or the second logic active region 52b. Therefore, the thickness (or height) of the first nitride insulating layer 18b remaining in the second trench T2 may be preferably determined within a range where the operation characteristics of the PMOS device does not deteriorate.

According to some embodiments, in the PMOS region including the first logic active region 52a and the second logic active region 52b, the deterioration of the operation characteristics of the PMOS device due to the first nitride insulating layer 18b may not occur. At the same time, the spacing between the logic active regions in the peripheral region PR may be reduced to the extent of the spacing between the memory active regions in the cell region CR in the long axis direction. Therefore, even though the first nitride insulating layer 18b may remain partially in the device isolation insulating layer in the second trench T2, the operation characteristics of the PMOS device may not deteriorate and the entire size of the semiconductor memory device 1 may also decrease in the X and/or Y directions thereof.

As shown in FIG. 15, the surface profile of the first nitride insulating layer 18b formed in the first trench T11 and the second trench T2 may have a downwardly concave shape depending on the etching conditions for the first nitride insulating layer 18b or the shapes of the first trench T11 and the second trench T2. That is, such a surface profile may appear when an etching speed of the first nitride insulating layer 18b is relatively fast near centers of the first trench T11 and the second trench T2.

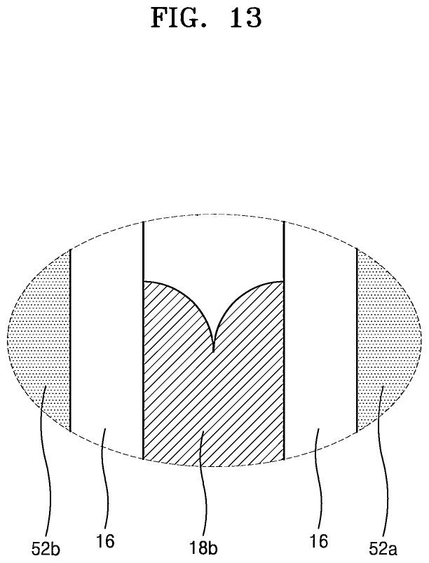

Referring to FIG. 13, a surface profile according to another embodiment corresponding to the ‘B’ part of FIG. 15 is illustrated. In FIG. 13, when the etching speed of the first nitride insulating layer 18b is relatively fast near the center of the second trench T2 and relatively slow on both side walls of the second trench T2 bordering the center of the second trench T2, the surface profile of the first nitride insulating layer 18b may have upwardly convex shapes towards both side walls of the second trench T2 bordering the center of the second trench T2.

Referring to FIG. 16, the second insulating layer 34 and a third insulating layer 36 may be formed sequentially on the entire exposure surface of the result of FIG. 15. The second insulating layer 34 may include an oxide-based insulating layer, such as a silicon oxide insulating layer. The second insulating layer 34 may be formed to fill all the remaining portions of the first trench T11 and the second trench T2. Subsequently, the third insulating layer 36 may have an etch selectivity with respect to the second insulating layer 34 depending on etching conditions. The third insulating layer 22 may include a nitride-based insulating layer, such as a silicon nitride insulating layer. The third trench T3 may not be completely filled with the second insulating layer 30. On the other hand, the device isolation insulating layers formed on left and right sides of the third trench T3 in the boundary region BR may be formed symmetrically.

Subsequently, referring again to FIG. 12, a fifth insulating layer 28a and the sixth insulating layer 29a may be sequentially formed on the result of FIG. 16 and may fill the third trench T3 completely. Then, through appropriate etching processes, portions of the fifth insulating layer 28a and the sixth insulating layer 29a may remain only in the central portion of the third trench T3. The fifth insulating layer 28a may be a nitride-based insulating layer, for example, a silicon nitride insulating layer, and the sixth insulating layer 29a may be an oxide-based insulating layer, for example, a TOSZ layer.

As described above, according to some embodiments, in the PMOS region including the first logic active region 52a and the second logic active region 52b, even though the first nitride insulating layer 18b may remain in the first logic active region 52a and the second logic active region 52b, the deterioration of the operation characteristics of the PMOS device due to the first nitride insulating layer 18b may not occur. At the same time, the spacing between the logic active regions in the peripheral region PR may be reduced to the extent of the spacing between the memory active regions in the cell region CR in the long axis direction. Thus, the total size in the X and/or Y directions of the semiconductor memory device 1 may also decrease.

FIG. 17 is a cross-sectional view showing a semiconductor memory device according to some embodiments. FIG. 17 is a cross-sectional view taken along a line A-A′ of FIG. 2. Descriptions that may be redundant or overlap the descriptions of embodiments related to FIGS. 3 to 11 may be briefly described or omitted.

Referring to FIG. 17 together with FIG. 2, in the cell region CR, the plurality of memory active regions formed on the upper portion of the semiconductor substrate 10 may include the first memory active region 12a, the second memory active region 12b, the third memory active region 12c, and the fourth memory active region 12d sequentially formed toward the inside of the cell region CR. In the peripheral region PR, the first logic active region 52a and the second logic active region 52b may be sequentially formed towards the outside of the semiconductor memory device. Although not indicated by reference numbers in FIG. 12, the first trenches (T11 and T12 in FIG. 5), the second trench (T2 in FIG. 5) and the third trench (T3 in FIG. 5) may be formed in positions corresponding to those in FIG. 5, respectively. In addition, the distances D3, D4, D5, and D6 are the same as the distances shown in FIG. 5. The peripheral region PR may be the PMOS region where at least the PMOS device, for example, the PMOS transistors are formed.

A first portion of the device isolation insulating layer formed in the first trench T11 between the first memory active region 12a and the second memory active region 12b and between the third memory active region 12c and the fourth memory active region 12d may include a first nitride insulating layer 44a whose bottom is not close to the bottom of the first trench T11 relative to the previous examples, but is located at a significant height from the bottom of the first trench T11. In addition, the device isolation insulating layer formed in the trench T2 between the first logic active region 52a and the second logic active region 52b in the peripheral region PR may not include the first nitride insulating layer having the same material or approximately the same shape as the first nitride insulating layer 44a formed in the first trench T11.

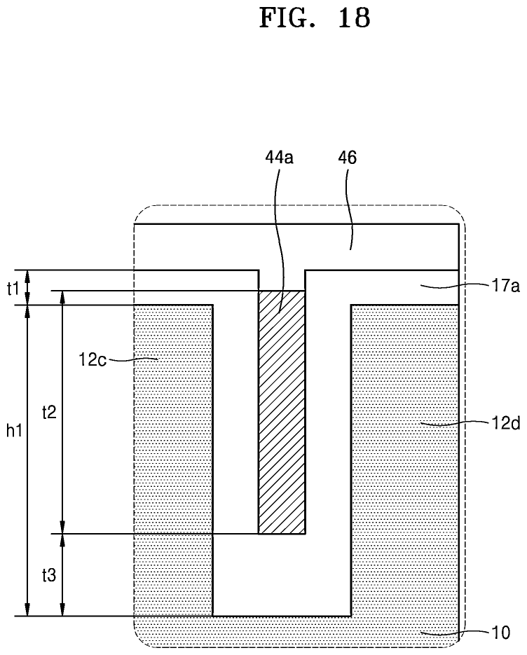

FIG. 18 is an enlarged cross-sectional view of portion ‘C’ of FIG. 17. Referring to FIG. 18, in the vicinity of the first trench T11, the thickness t3 of the first insulating layer 17a at the bottom of the first trench T11 may be greater than the thickness t1 of the first insulating layer 17a at the top of the third memory active region 12c and the fourth memory active region 12d. Therefore, a lower end of the first nitride insulating layer 44a in the first trench T11 may be at a vertical level higher than an upper end of a horizontal portion of the first insulating layer 17a formed in the third trench T3. Although not shown specifically, in some embodiments, in the vicinity of the first trench T11, the thickness t3 of the first insulating layer 17a at the bottom of the first trench T11 may be less than the thickness t1 of the first insulating layer 17a at the top of the third memory active region 12c and the fourth memory active region 12d. Therefore, the lower end of the first nitride insulating layer 44a in the first trench T11 may be at a vertical level lower than the upper end of a horizontal portion of the first insulating layer 17a formed in the third trench T3. In other words, in some embodiments, the vertical level of the first nitride insulating layer 44a formed in the first trench T11 may be arbitrarily adjusted as needed, as described later with respect to the semiconductor memory device.

According to some embodiments, even though the spacing between the logic active regions in the peripheral region PR may be reduced to the spacing between the memory active regions in the cell region CR (e.g., D3≈D5), since the first nitride insulating layer 44a may not remain in the device isolation insulating layer in the second trench T2 in the peripheral region PR, the operation characteristics of the PMOS device may not deteriorate and at the same time, the entire size in the X and Y directions of the semiconductor memory device 1 may decrease.

In some embodiments, the device isolation insulating layers respectively formed in the first portion of the first trench T11, the second portion of the first trench T12, the second trench T2, and the third trench T3 which surround the plurality of memory active regions and the plurality of logic active regions may be formed in different shapes.

The device isolation insulating layer formed in the first portion of the first trench T11 may include a first insulating layer 17a, a first nitride insulating layer 44a, and a second insulating layer 46 that are sequentially stacked. In some embodiments, the first insulating layer 17a may include an oxide-based insulating layer, for example, a silicon oxide insulating layer, but is not limited thereto. The first nitride insulating layer 44a may include a nitride-based insulating layer, for example a silicon nitride insulating layer, and is not limited thereto. The second insulating layer 46 may include, for example, an oxide-based insulating layer, or a silicon oxide insulating layer, but is not limited thereto. The device isolation insulating layer formed in the first portion of the first trench T11 may include the first insulating layer 17a and the second insulating layer 46 that are sequentially stacked.

The device isolation insulating layer formed in the second trench T2 in the peripheral region PR may include the first insulating layer 17a and the second insulating layer 46 sequentially stacked in the same manner as the device isolation insulating layer formed in the second portion of the first trench T12.

The device isolation insulating layer formed in the third trench T3 in the boundary region BR may be formed to be approximately left-right symmetrical. Specifically, the device isolation insulating layer formed in the third trench T3 may include the first insulating layer 17a and the second insulating layer 46 sequentially stacked from the bottom of the third trench T3. In addition, in the central portion of the third trench T3, a fifth insulating layer 28a, and a sixth insulating layer 29a may be formed on the second insulating layer 46 to completely fill the third trench T3. The fifth insulating layer 28a may be a nitride-based insulating layer, for example, a silicon nitride insulating layer, and the sixth insulating layer 29a may be an oxide-based insulating layer, for example, a TOSZ® layer.

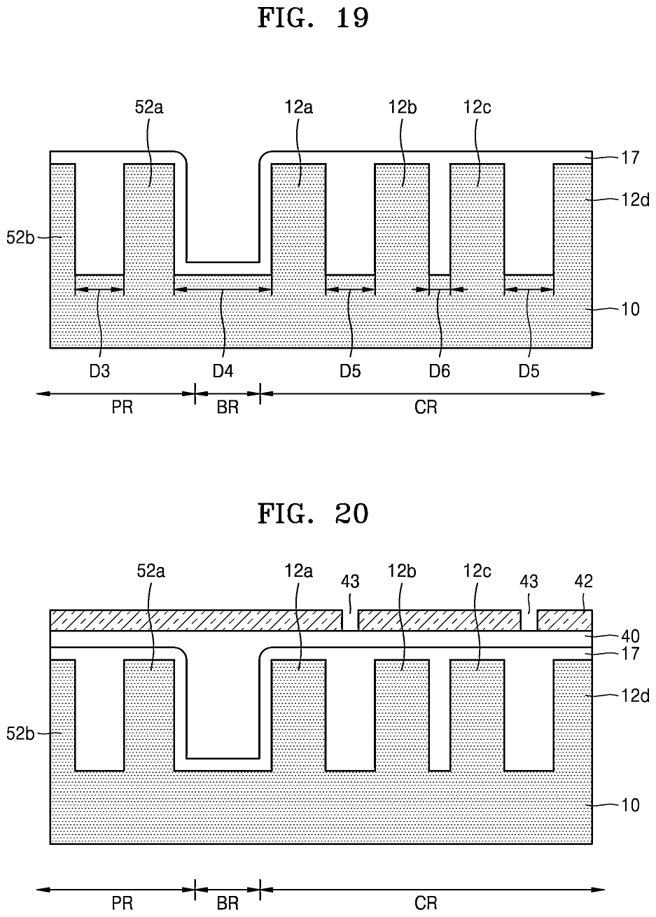

FIGS. 19 to 23 are cross-sectional views sequentially showing states of a semiconductor device during a method of manufacturing a semiconductor memory device according to some embodiments. FIGS. 19 to 23 are cross-sectional views taken along a line A-A′ of FIG. 2. FIG. 17 is a cross-sectional view after performing a step of FIG. 23.

Referring to FIG. 19 with FIG. 2, the first memory active region 12a, the second memory active region 12b, the third memory active region 12c, the fourth memory active 12d, the first logic active region 52a, and the second logic active region 52b may be formed in an upper portion of the semiconductor substrate 10. The peripheral region PR may be a PMOS region where at least a PMOS device, for example, PMOS transistors are formed. The meaning and relative size of the distances D1, D2, D3, D4, D5, and D6 may be the same as those described with reference to FIG. 3. In particular, the distance D3 may be substantially the same as the distance D2 or the distance D5.

Subsequently, referring to FIG. 19, the first insulating layer 17 may be formed on an exposed entire surface of the semiconductor substrate 10 in which the plurality of memory active regions and the plurality of logic active regions are formed. Except for the third trench T3 formed in the boundary region BR, the first portion of the first trench T11, the second portion of the first trench T12, and the second trench T2 may be completely filled with the first insulating layer 17. The first insulating layer 17 may include an oxide-based insulating layer, for example, a silicon oxide insulating layer, and is not limited thereto.

Referring to FIG. 20, a relatively thick mask material layer 40 that may serve as an etch mask in a subsequent process, may be formed on the semiconductor memory device shown in the state of FIG. 19. The third trench T3 may be completely filled with the mask material layer 40. The mask material layer 40 may be formed of various material layers that may serve as the etch mask in the subsequent process. As the mask material layer 40, for example, a spin on hardmask (SOH) coating layer that may fill a gap such as a trench and may have excellent surface planarization characteristics and etch resistance as an auxiliary material for implementing semiconductor micro patterns, may be used. As needed, a plasma enhanced SiON layer may be further deposited on the SOH coating layer.

A mask pattern 42 may be then formed on the mask material layer 40. The mask pattern 42 may include a photosensitive material for the photolithography process, for example, a photoresist. First openings 43 may be formed in the mask pattern 42 to expose specific positions of the underlying mask material layer 40. The first openings 43 may selectively expose the specific positions in the cell region CR, and in some embodiments, the specific positions may correspond to portions of the first trench T11 where the device isolation insulating layer is located in the long axis direction of the memory active regions.

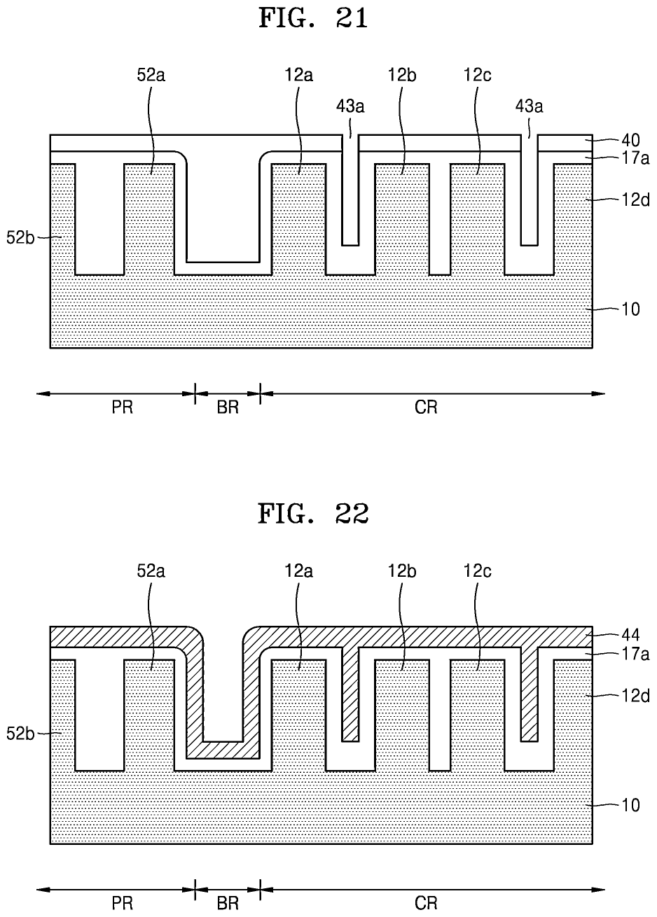

Referring to FIG. 21, when portions of the mask material layer 40 are etched using the mask pattern 42 as the etch mask, second openings 43a may be formed in positions corresponding to the first openings 43 of the mask pattern 42. Subsequently, the mask material layer 40 in which the second openings 43a are formed may be used as the etch mask, to etch and remove the first insulating layer 17 exposed by the second openings 43a to a certain depth.

At this time, as described above with reference to FIG. 18, the depth of the first insulating layer 17 to be etched may be arbitrarily adjusted by the needs according to the operation characteristics of the semiconductor memory device 1 or the etching conditions thereof. As will be described later, since etched portions of the first insulating layer 17 may be portions where the first nitride insulating layer 44a will be formed, the depth of the first insulating layer 17 to be etched may be adjusted in various ways according to the characteristics of the first nitride insulating layer 44a. In some embodiments, the etched depth of the first insulating layer 17 may reach the bottom of the first trench T11. In some embodiments, a lower end of an etched portion of the first insulating layer 17a may be located at a position lower than, equal to, or higher than the vertical level of a top of the first insulating layer 17a that is formed at the bottom of the third trench T3.

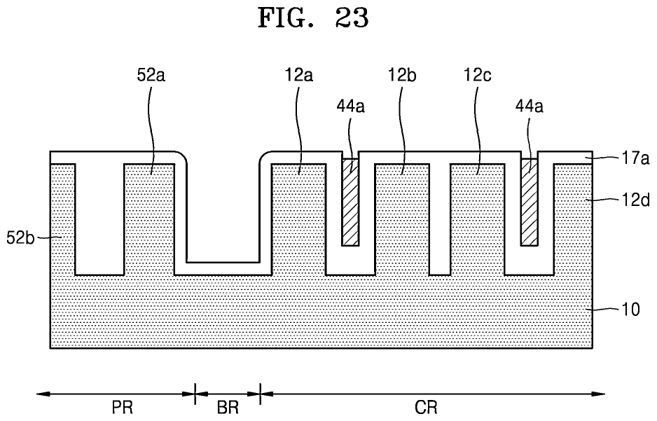

Referring to FIG. 22, the mask material layer 40 may be removed from the result of FIG. 21, for example, through a strip process, and then a first nitride insulating layer 44 may be formed on the entire surface of the exposed first insulating layer 17a. The first nitride insulating layer 44 may be formed at a certain thickness along the bottom and sidewalls of the third trench T3 while completely filling the first portion of the first trench T11.

Referring to FIG. 23, the first nitride insulating layer 44 may be removed from other portions, for example, through the strip process, so that the first nitride insulating layer 44a remains only within the first portion of the first trench T11.

Referring again to FIG. 17, the second insulating layer 46 may be formed on the entire exposure surface of the result of FIG. 23. The second insulating layer 46 may include an oxide-based insulating layer, such as a silicon oxide insulating layer. Subsequently, the fifth insulating layer 28a and the sixth insulating layer 29a may be sequentially formed on the second insulating layer 46 to completely fill the third trench T3. Then, through appropriate etching processes, portions of the fifth insulating layer 28a and the sixth insulating layer 29a may remain only in the central portion of the third trench T3. The fifth insulating layer 28a may be a nitride-based insulating layer, for example, a silicon nitride insulating layer, and the sixth insulating layer 29a may be an oxide-based insulating layer, for example, a TOSZ® layer.

As described above, according to some embodiments, in the PMOS region including the first logic active region 52a and the second logic active region 52b, since the first nitride insulating layer 44a is not present in the device isolation insulating layer between the first logic active region 52a and the second logic active region 52b, the deterioration of the operation characteristics of the PMOS device due to the first nitride insulating layer 44a may not occur. At the same time, the spacing (i.e., the distance D3) between the logic active regions in the peripheral region PR may be reduced to the extent of the spacing (for example, the distance D5 or D2) between the memory active regions in the cell region CR in the long axis direction. Thus, the total size in the X and/or Y directions of the semiconductor memory device 1 may also decrease.

While the inventive concept has been particularly shown and described with reference to embodiments thereof, it will be understood that various changes in form and details may be made therein without departing from the spirit and scope of the following claims.

What is claimed is:

1. A semiconductor memory device, comprising:
a semiconductor substrate comprising a cell portion in a cell region, a peripheral portion in a peripheral region disposed around the cell region, and a boundary portion in a boundary region between the cell region and the peripheral region;
a plurality of memory active regions defined by a first trench in the cell region, each of the memory active regions having a long axis and a short axis, wherein each of the memory active regions is arranged to maintain a first distance between adjacent memory active regions along a direction of the short axis and each of the memory active regions is arranged to maintain a second distance between adjacent memory active regions along a direction of the long axis;
a plurality of logic active regions defined by a second trench in the peripheral region, wherein each of the logic active regions comprises at least a P-channel metal oxide semiconductor (PMOS) transistor, and each of the logic active regions is arranged to maintain a third distance between adjacent logic active regions;
a first device isolation insulating layer partially formed in the first trench, wherein a first portion of the first device isolation insulating layer that corresponds to a region between the memory active regions that are adjacent to each other along the direction of the long axis comprises a first nitride insulating layer; and
a second device isolation insulating layer partially formed in the second trench between the logic active regions and that does not include the first nitride insulating layer, and wherein the second distance is substantially the same as the third distance.

2. The semiconductor memory device of claim 1, wherein
a second portion of the first device isolation insulating layer that corresponds to a region between the memory active regions that are adjacent to each other along the direction of the short axis does not include the first nitride insulating layer.

3. The semiconductor memory device of claim 1, wherein
the first portion of the first device isolation insulating layer further comprises a first insulating layer, the first nitride insulating layer, a second insulating layer, a third insulating layer, and a fourth insulating layer, wherein the first insulating layer, the first nitride insulating layer, the second insulating layer, the third insulating layer, and the fourth insulating layer are sequentially stacked in order, and the second device isolation insulating layer that is partially formed in the second trench between the logic active regions comprises the first insulating layer and the fourth insulating layer, wherein the first insulating layer and the fourth insulating layer are sequentially stacked in order.

4. The semiconductor memory device of claim 3, wherein
a second portion of the first device isolation insulating layer that is formed between the memory active regions adjacent to each other along the direction of the short axis comprises the first insulating layer, the second insulating layer, the third insulating layer, and the fourth insulating layer, wherein the first insulating layer, the second insulating layer, the third insulating layer, and the fourth insulating layer are sequentially stacked in order.

5. The semiconductor memory device of claim 3, further comprising:
a third device isolation insulating layer in the boundary region that is partially formed in a third trench between an outermost memory active region of the plurality of memory active regions and an innermost logic active region of the plurality of logic active regions, wherein the third device isolation insulating layer is asymmetrically formed in a vertical cross-section traversing the boundary region between the innermost logic active region and the outermost memory active region.

6. The semiconductor memory device of claim 5, wherein
a first portion of the third device isolation insulating layer in contact with the outermost memory active region comprises the first insulating layer, the second insulating layer, the third insulating layer, and the fourth insulating layer, wherein the first insulating layer, the second insulating layer, the third insulating layer, and the fourth insulating layer are sequentially stacked in order, and a second portion of the third device isolation insulating layer in contact with the innermost logic active region comprises the first insulating layer and the fourth insulating layer without the second insulating layer and the third insulating layer, wherein the first insulating layer and the fourth insulating layer are sequentially stacked in order.

7. The semiconductor memory device of claim 6, wherein
an end of each of the second insulating layer and the third insulating layer in the first portion of the third device isolation insulating layer protrude horizontally toward a central region of the third trench in a tail shape.

8. The semiconductor memory device of claim 6, wherein
a fifth insulating layer and a sixth insulating layer are formed sequentially on the fourth insulating layer of the first portion of the third device isolation insulating layer and on the fourth insulating layer of the second portion of the third device isolation insulating layer.

9. The semiconductor memory device of claim 1, wherein
the first portion of the first device isolation insulating layer further comprises a first insulating layer and a second insulating layer, wherein the first insulating layer, the first nitride insulating layer, and the second insulating layer are sequentially stacked in order, and the second device isolation insulating layer between the logic active regions comprises the first insulating layer and the second insulating layer, wherein the first insulating layer and the second insulating layer are sequentially stacked in order.

10. The semiconductor memory device of claim 9, further comprising:
a third device isolation insulating layer in the boundary region that is partially formed in a third trench between an outermost memory active region of the plurality of memory active regions and an innermost logic active region of the plurality of logic active regions, wherein the third device isolation insulating layer is symmetrically formed in a vertical cross-section traversing the boundary region between the innermost logic active region and the outermost memory active region.

11. The semiconductor memory device of claim 10, wherein
the third device isolation insulating layer partially formed in the third trench comprises the first insulating layer, the second insulating layer, a fifth insulating layer, and a sixth insulating layer, wherein the first insulating layer, the second insulating layer, the fifth insulating layer, and the sixth insulating layer are sequentially formed to fill the third trench.

12. The semiconductor memory device of claim 10, wherein
a vertical level of a lower end of the first nitride insulating layer of the first portion of the first device isolation insulating layer is higher than a vertical level of an upper end of the first insulating layer of the third device isolation insulating layer formed at a bottom of the third trench.

13. A semiconductor memory device comprising:
a semiconductor substrate comprising a cell region, a peripheral region disposed around the cell region, and a boundary region between the cell region and the peripheral region;
a plurality of memory active regions defined by a first trench in the cell region, each of the memory active regions having a long axis and a short axis, wherein each of the memory active regions is arranged to maintain a first distance between adjacent memory active regions along a direction of the short axis and each of the memory active regions is arranged to maintain a second distance between adjacent memory active regions along a direction of the long axis; and
a plurality of logic active regions defined by a second trench in the peripheral region, wherein each of the logic active regions comprise at least a P-channel metal oxide semiconductor (PMOS) transistor, and each of the logic active regions is arranged to maintain a third distance between adjacent logic active regions;
a first device isolation insulating layer partially formed in the first trench, wherein a first portion of the first device isolation insulating layer that corresponds to a region between the memory active regions that are adjacent to each other along the direction of the long axis comprises a first nitride insulating layer; and
a second device isolation insulating layer partially formed in the second trench, wherein the second device isolation insulating layer comprises the first nitride insulating layer, and
wherein the second distance is substantially the same as the third distance, and
a vertical level of an upper end of the first nitride insulating layer of the second device isolation insulating layer is located at half of the depth of the second trench or below.

14. The semiconductor memory device of claim 13, wherein
an upper end of the first nitride insulating layer of the first portion of the first device isolation insulating layer and an upper end of the first nitride insulating layer of the second device isolation insulating layer are located at the same vertical level.

15. The semiconductor memory device of claim 13, wherein
the first portion of the first device isolation insulating layer and the second device isolation insulating layer each further comprise a first insulating layer and a second insulating layer, wherein the first insulating layer, the first nitride insulating layer, and the second insulating layer are sequentially stacked in order.

16. The semiconductor memory device of claim 13, further comprising:
a third device isolation insulating layer in the boundary region that is formed partially in a third trench between an outermost memory active region of the plurality of memory active regions and an innermost logic active region of the plurality of logic active regions, wherein the third device isolation insulating layer is symmetrically formed in a vertical cross-section traversing the boundary region between the innermost logic active region and the outermost memory active region.

17. The semiconductor memory device of claim 16, wherein
the third device isolation insulating layer comprises a first insulating layer, a second nitride insulating layer different from the first nitride insulating layer, and a third insulating layer, wherein the first insulating layer, the second nitride insulating layer, and the third insulating layer are sequentially formed to fill the third trench.

18. A semiconductor memory device comprising:
a semiconductor substrate comprising a cell region, a peripheral region disposed around the cell region, and a boundary region between the cell region and the peripheral region;
a plurality of memory active regions defined by a first trench in the cell region, each of the memory active regions having a long axis and a short axis, wherein each of the memory active regions is arranged to maintain a first distance between adjacent memory active regions along a direction of the short axis and each of the memory active regions is arranged to maintain a second distance between adjacent memory active regions along a direction of the long axis;
a plurality of logic active regions defined by a second trench in the peripheral region, wherein the plurality of logic active regions comprise at least a P-channel metal oxide semiconductor (PMOS) transistor, and the plurality of logic active regions adjacent to each other are arranged while maintaining a third distance therebetween,
a first device isolation insulating layer that is partially formed in the first trench and that comprises a first silicon nitride layer formed below an upper end of the first trench;
a second device isolation insulating layer that is partially formed in the second trench between logic active regions that are adjacent to each other and that does not include the first silicon nitride layer; and
a third device isolation insulating layer that is partially formed in a third trench in the boundary region between an outermost memory active region of the plurality of memory active regions and an innermost logic active region of the plurality of logic active regions, wherein the third device isolation insulating layer is asymmetrically formed in a vertical cross-section traversing the boundary region between the innermost logic active region and the outermost memory active region; and
wherein the second distance is substantially the same as the third distance.

19. The semiconductor memory device of claim 18, wherein
the first device isolation insulating layer between the memory active regions adjacent to each other along the direction of the long axis comprises a first oxide layer, the first silicon nitride layer, a second silicon nitride layer, a second oxide layer, and a third oxide layer, wherein the first oxide layer, the first silicon nitride layer, the second silicon nitride layer, the second oxide layer, and the third oxide layer are sequentially stacked and the second silicon nitride layer is thinner than the first silicon nitride layer in the stacking direction, and the second device isolation insulating layer between the logic active regions comprises the first oxide layer and the third oxide layer, wherein the first oxide layer and the third oxide layer are sequentially stacked.

20. The semiconductor memory device of claim 19, wherein
ends of the second silicon nitride layer and the second oxide layer in portions of the third device isolation insulating layer contacting the outermost memory active region protrude horizontally toward a central region of the third trench in a tail shape.
